(19) United States
(12) Patent Application Publication
(10) Pub. No.: US 2025/0355042 A1
(43) Pub. Date: Nov. 20, 2025

(54) COMPARATOR CIRCUIT SELF-TEST

(71) Applicant: Infineon Technologies AG, Neubiberg (DE)

(72) Inventors: Alexandru VARLAN, Piatra Neamt (RO); Florin BIZIITU, Bucharest (RO); Cristian MURTAZA, Bucharest (RO)

(21) Appl. No.: 19/209,172

(22) Filed: May 15, 2025

(30) Foreign Application Priority Data
May 16, 2024 (DE) 102024204534.9

(51) Int. Cl. G01R 31/317; G01R 31/00; H03K 5/24

(52) U.S. Cl. CPC G01R 31/31703; G01R 31/006; H03K 5/24

(57) ABSTRACT

A circuit arrangement comprises a comparator circuit configured for comparing a voltage to a provided reference voltage and a time evaluation circuit configured for determining a time interval between a start signal and a stop signal. The circuit arrangement further comprises a voltage ramp generation circuit configured for generating a voltage ramp beginning with the start signal. In a normal operation mode, the circuit arrangement is configured for comparing an input voltage to the reference voltage by using the comparator circuit. In a self-test mode for performing a self-test of the comparator circuit, the circuit arrangement is configured for generating a voltage ramp by using the voltage ramp generation circuit, for continuously comparing the generated voltage ramp to the reference voltage by using the comparator circuit and for determining a time interval in which the generated voltage ramp reaches the reference voltage by using the time evaluation circuit.

### TECHNICAL FIELD

The present disclosure relates to a circuit arrangement, a method for performing a self-test of a comparator circuit and a use thereof.

### BACKGROUND

Comparator circuits can be used for various purposes. As an example, in safety relevant applications, a comparator circuit may be used for comparing an input to a threshold which should not be exceeded in faultless operation. The threshold may for instance refer to an overvoltage threshold, an overcurrent threshold or an overtemperature threshold and is typically provided in form of a reference voltage in the comparator circuit. Thus, the comparator circuit typically compares the reference voltage with an input voltage. In case of a fault operation, for instance due to a degradation of an element, safety precautions must typically be taken. As indicated, the comparator circuit may identify such a fault operation by comparing the input voltage to the reference voltage and may output a signal for initiating such a safety precaution. As an example, the comparator may output a low voltage as long as the input voltage is below the reference voltage and a high voltage as soon as the input voltage exceeds the reference voltage. Accuracy of the comparator circuit is typically crucial, specifically for safety relevant applications. The comparator circuit must not only functionally be capable of switching between outputs, but also the reference voltage must typically be precise and must remain stable. Thus, there is a need for improving reliability of comparator circuits and specifically for controlling accuracy of the used reference voltages.

### SUMMARY

In a first aspect, a circuit arrangement is presented. The circuit arrangement comprises a comparator circuit. The comparator circuit is configured for comparing a voltage to a provided reference voltage. The circuit arrangement further comprises a time evaluation circuit. The time evaluation circuit is configured for determining a time interval between a start signal and a stop signal. The circuit arrangement further comprises a voltage ramp generation circuit. The voltage ramp generation circuit is configured for generating a voltage ramp beginning with the start signal. In a normal operation mode, the circuit arrangement is configured for comparing an input voltage to the reference voltage by using the comparator circuit. In a self-test mode for performing a self-test of the comparator circuit, the circuit arrangement is configured for generating a voltage ramp by using the voltage ramp generation circuit, for continuously comparing the generated voltage ramp to the reference voltage by using the comparator circuit and for determining a time interval in which the generated voltage ramp reaches the reference voltage by using the time evaluation circuit.

In a further aspect, a method for performing a self-test of a comparator circuit is presented. The method comprises:
a) generating a voltage ramp by using a voltage ramp generation circuit;
b) continuously comparing the generated voltage ramp to a provided reference voltage by using the comparator circuit; and
c) determining a time interval in which the generated voltage ramp reaches the reference voltage by using a time evaluation circuit.

In a further aspect, a use of the circuit arrangement or of the method is presented for an automotive application.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates an example of a circuit arrangement according to the present disclosure;

FIG. 2 schematically illustrates a signal progression in the circuit arrangement over time; and

FIG. 3 illustrates a flow chart of an example of a method for performing a self-test of a comparator circuit according to the present disclosure.

### DETAILED DESCRIPTION

The examples described herein provide considerable advantages. Specifically, they can improve the reliability of comparator circuits, which may in particular be important for safety relevant applications. More specifically, they may control and, if required, adjust a provided reference voltage in the comparator circuits. Thus, a precise and stable reference voltage may be ensured, which can for instance be used as a threshold for identifying a fault operation. The accuracy of the reference voltage can specifically be ensured by implementing a self-test mechanism, which may be performed without requiring a plurality of additional components. Since a comparator circuit is typically a part of a superordinate circuit, specifically of a superordinate integrated circuit, which typically comprise various components for different purposes, those components may additionally be used for performing the addressed self-test. Thus, with the provided approach, the reliability of the comparator circuit can be improved in a robust fashion and at a low cost, for instance in terms of system complexity or in terms of spent area on a semiconductor die in an integrated circuit.

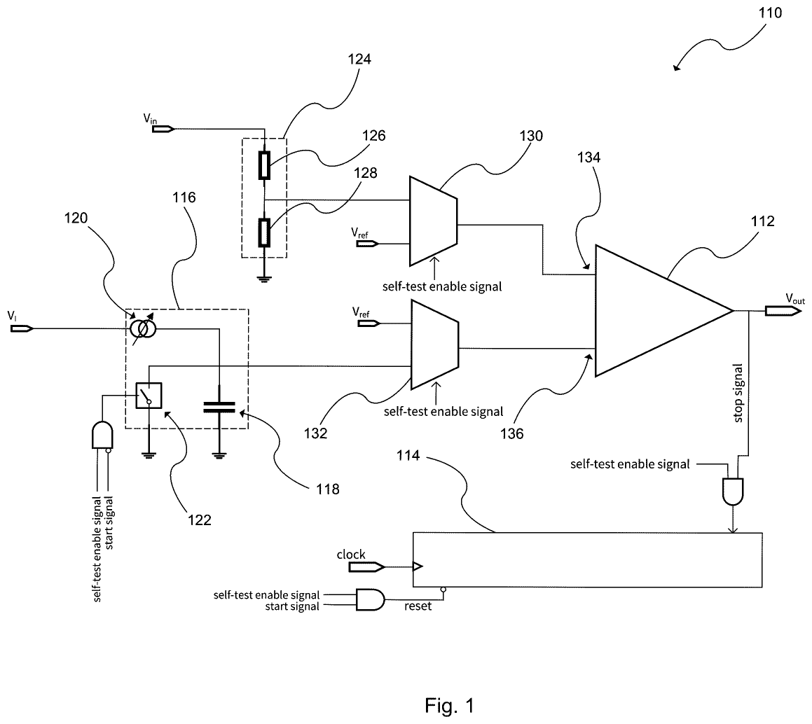

FIG. 1 schematically illustrates an example of a circuit arrangement 110. The circuit arrangement 110 may be a superordinate circuit comprising a plurality of subordinate circuits. The subordinate circuits may at least partially be interconnected, such as by using wires or traces. A circuit may generally comprise at least one electronic component, for instance a transistor, a resistor, a capacitor or an inductor. Specifically, the circuit may comprise a plurality of electronic components, which are also at least partially interconnected. Specifically, the circuit arrangement 110 may be an integrated circuit or may comprise an integrated circuit or may be part of an integrated circuit. Thus, the circuit arrangement 110 may be arranged on a semiconductor die. As an example, silicon, silicon carbide or gallium nitride may be used as semiconductor material of the semiconductor die. Other options are of course also feasible.

The circuit arrangement 110 comprises a comparator circuit 112. The comparator circuit 112 is configured for comparing a voltage to a provided reference voltage. The comparator circuit 112 may be an arbitrary circuit configured for comparing at least two voltages. Thus, an output of the comparator circuit 112 may indicate which input voltage is higher. Various embodiments of a comparator circuit are generally known to the skilled person and may be applied for realizing the comparator circuit 112, specifically for realizing an internal circuitry of the comparator circuit 112. As indicated, the comparator circuit 112 may compare two voltages, one of which may specifically be a reference voltage. The reference voltage is indicated by the abbreviation V_{ref} in the figures. The reference voltage may be predetermined. Thus, the reference voltage may be set at a predetermined value, for instance at a threshold for identifying a fault operation. As an example, the reference voltage may be an overvoltage threshold. Additionally or alternatively, the reference voltage may for instance be a predetermined voltage value referring an overcurrent threshold or an overtemperature threshold. However, the reference voltage may also be variable. The reference voltage may be instable over time, such as due to an instability of a voltage source. As a result, detection of a fault operation may be compromised. Thus, for ensuring a reliable detection of the fault operation and further protection of a corresponding device, said variation should be identified and possibly also compensated, such as by recalibrating or readjusting the reference voltage to an original value.

The circuit arrangement 110 further comprises a time evaluation circuit 114. The time evaluation circuit 114 is configured for determining a time interval between a start signal and a stop signal. The start signal and/or the stop signal may be provided to a plurality of components of the circuit arrangement 110, specifically to the time evaluation 114 and/or a voltage ramp generation circuit 116, which will be described in further detail below. As the name already implies, the start signal may indicate a start or a beginning of a process and the end signal may indicate a stop or an end of the process. The process may specifically involve a plurality of components of the circuit arrangement 110, specifically the comparator circuit 112, the time evaluation circuit 114 and the voltage ramp generation circuit 116. As will also be outlined in further detail below, the process may specifically be a self-test of the comparator circuit 112. Thus, the time evaluation circuit 114 may be configured for recording a time span of the self-test.

Again, various embodiments of a time evaluation circuit are generally known to the skilled person and may be applied for realizing the time evaluation circuit 114. Specifically, the time evaluation circuit 114 may be or may comprise a counter, for instance a 7 bit counter. The counter may be configured to start counting with the start signal and to stop counting with the stop signal. The time evaluation circuit 114, specifically the counter, may further comprise a clock input. Thus, the time evaluation circuit 114, specifically the counter, may be configured for counting clock periods. The clock may for instance be an oscillator or may comprise an oscillator, such as a 75 MHz oscillator. Thus, the counter may count oscillator periods, for instance 75 MHz oscillator periods. Such clocks, or specifically oscillators, are typically already part of an integrated circuit in many applications. Thus, for performing the addressed self-test, no further time evaluation circuit besides the already existing one may be required. This May generally reduce system complexity and, in an integrated circuit, this may specifically spare area on the semiconductor die which can for instance be used otherwise. For performing the self-test, in order to improve the accuracy of the reference voltage, the time evaluation circuit 114 should obviously be as precise as possible. However, again, this is typically already fulfilled for clocks, or specifically for oscillators, in an integrated circuit, which have a variation in the range of typically only 1%.

As already indicated, the circuit arrangement 110 further comprises the voltage ramp generation circuit 116. The voltage ramp generation circuit 116 is configured for generation a voltage ramp beginning with the start signal. Thus, as said, the start signal may specifically be provided to both the voltage ramp generation circuit 116 and the time evaluation circuit 114, which may be coupled in that sense. Again, various embodiments of a voltage ramp generation circuit are generally known to the skilled person and may be applied for realizing the time voltage ramp generation circuit 116. Specifically, the voltage ramp generation circuit 116 may comprise a capacitor 118. The capacitor 118 may be configured for generating the voltage ramp and applying the voltage ramp to the comparator circuit 112 by accumulating electric charges. As generally known, the voltage generated by capacitors increases linearly with increasing electric charge stored in them, such that over time a voltage ramp is generated when charging them.

The voltage ramp generation circuit 116 may further comprise a current source 120. The current source 120 may be configured for supplying the capacitor 118 with the electric charges. Thus, the current source 120 may be connected to the capacitor 118. The current source 120 may specifically be a constant current source. Thus, the current source 120 may specifically constantly charge the capacitor 118 over time. The current source 120 may be supplied by a supply voltage V_{I}. Thus, a current from the current source 120 may charge the capacitor 118 which may result in a continuously and specifically linearly increasing voltage generated by the capacitor 118. The current source 120 may further specifically be a trimmable current source. In manufacturing, capacitances of the capacitor 118 may vary from device to device, which may result in different voltage ramps being generated. Such a variation may specifically be compensated by trimming the current source 120 accordingly at the end of manufacturing. By doing so, high precision of the voltage ramp generation circuit 116 can be ensured, which may again be beneficial for improving the accuracy of the reference voltage.

The voltage ramp generation circuit 116 may further comprise a discharge switch 122. The discharge switch 122 may for instance be a transistor. The discharge switch 122 may be configured for discharging the capacitor 118 with the start signal. The discharge switch 122 may thus for instance be connected to the capacitor 118 and to ground. When performing the self-test and when receiving the start signal, i.e. at the beginning of the self-test, the discharge switch 122 may then discharge the capacitor 118 to ground, such that the capacitor 118 can again be charged by the current source 120 for generating the voltage ramp. Thus, when performing the self-test and when not receiving the start signal, i.e. in the course of the self-test, the discharge switch 122 may be opened again, such that it may not directly discharge the capacitor 118.

The circuit arrangement 110 or specifically the comparator circuit 112 may have two operation modes: a normal operation mode and a self-test mode. In the normal operation mode, the circuit arrangement 110 is configured for comparing an input voltage to the reference voltage by using the comparator circuit 112. The input voltage may be an arbitrary voltage of interest. The input voltage may be provided by an external voltage supply. Depending on the application, the input voltage may for instance be a supply voltage for a device. Thus, in the normal operation mode, the comparator circuit 112 may monitor if the input voltage is within an acceptable range or if the input voltage exceeds a threshold indicating a fault operation. In FIG. 1, the input voltage is indicated by the abbreviation Vin. The input voltage may directly or indirectly be applied to the comparator circuit 112 for comparing the input voltage with the reference voltage. Specifically, the input voltage may be adapted by using a voltage divider 124 before applying it to the comparator circuit 112, for instance due a limited compatible voltage range of the comparator circuit 112. As an example, the voltage divider 124 may comprise a resistor 126 and a resistor 128.

In the self-test mode, the circuit arrangement 110 is configured for generating a voltage ramp by using the voltage ramp generation circuit 116, for continuously comparing the generated voltage ramp to the reference voltage by using the comparator circuit 112 and for determining the time interval in which the generated voltage ramp reaches the reference voltage by using the time evaluation circuit 114. The circuit arrangement 110, or more specifically its components, may switch from the normal operation mode to the self-test mode for controlling the accuracy of the comparator circuit 112 by using a self-test enable signal. Thus, when receiving the self-test mode enable signal, each component may switch operation to self-test mode accordingly. When receiving the self-test enable signal and the start signal, the time evaluation circuit 114 may be reset. Thus, as an example, the counter may start counting up again from 0. Further, when receiving the self-test enable signal and the start signal, the voltage ramp generation circuit 116 may start generating the voltage ramp, such as by discharging the capacitor 118 and afterwards continuously charging it again as described above.

The comparator circuit 112 may continuously compare the generated voltage ramp or in other words the present voltage value of the generated voltage ramp to the reference value. Thus, as soon as the generated voltage ramp reaches or exceeds the reference voltage, this may be indicated by the comparator circuit 112, such as by switching from a low voltage output to a high voltage output. In FIG. 1, the output voltage of the comparator circuit 112 is indicated by Vout. The output voltage of the comparator circuit 112 may also be fed as a stop signal into the time evaluation circuit 114. Thus, when receiving the self-test enable signal and the stop signal, which may for instance refer to a high voltage output of the comparator circuit 112, the time evaluation circuit 114 may stop recording the time. In other words, the comparator circuit 112 may further be configured for providing the stop signal to time evaluation circuit 114 if the generated voltage ramp reaches the reference voltage during the self-test of the comparator circuit 112. Thus, the self-test mode may be started with the start signal and stopped with the stop signal and, in the self-test mode, the time evaluation circuit 114 may track or record the time interval between the start signal and the stop signal.

The circuit arrangement 110 may further comprise multiplexers 130 and 132 configured for multiplexing the reference voltage, the input voltage and the generated voltage ramp. Specifically, the first multiplexer 130 may be configured for multiplexing the reference voltage and the input voltage at a first comparator input 134. More specifically, the first multiplexer 130 may be configured for applying the input voltage to the first comparator input 134 in the normal operation mode and for applying the reference voltage to the first comparator input 134 in the self-test mode. The second multiplexer 132 may be configured for multiplexing the reference voltage and the generated voltage ramp at a second comparator input 136. More specifically, the second multiplexer 132 may be configured for applying the reference voltage to the second comparator input 136 in the normal operation mode and for applying the generated voltage ramp to the second comparator input 136 in the self-test mode. Switching between the normal operation mode and the self-test mode may again be accomplished for the multiplexers 130 and 132 by using the above-mentioned self-test enable signal. Thus, in summary, in the normal operation mode, the comparator circuit 112 may compare the input voltage at the first comparator input 134 to the reference voltage at the second comparator input 136. In contrast, in the self-test mode, the comparator circuit 112 may compare the reference voltage at the first comparator input 134 to the generated voltage ramp at the second comparator input 136.

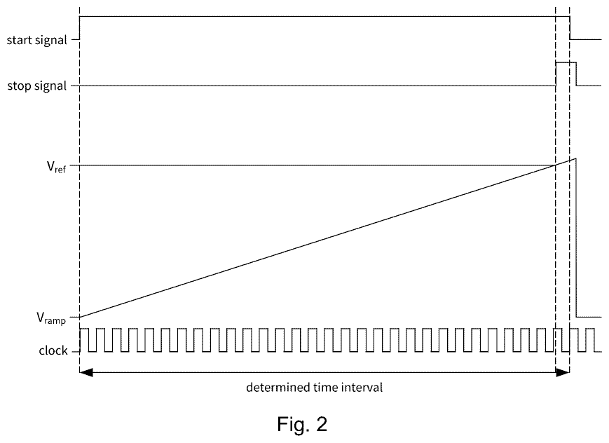

FIG. 2 schematically illustrates a signal progression in the circuit arrangement 110 over time, specifically in the self-test mode. As already described in further detail above, with a start signal the voltage ramp generation circuit 116 may start to generate a voltage ramp. In FIG. 2, the voltage ramp is indicated by the abbreviation Vramp. At the same time, the time evaluation circuit 114 may start recording time. Specifically, as also indicated in further detail above, the time evaluation circuit 114 may be or may comprise a counter having a clock input and the counter may start counting clock signals beginning with the start signal. The comparator circuit 112 may continuously compare the voltage ramp and the voltage reference as also described above in further detail. Once the voltage ramp reaches the voltage reference, the comparator circuit 112 may then indicate a stop signal to the time evaluation circuit 114. The time evaluation circuit 114 may then count a last clock period and may stop counting afterwards. Thus, a subsequent clock period received after the stop signal may not be counted anymore. More specifically, a rising flank of the subsequent clock period may not be taken into account anymore. As already indicated, a higher precision of the clock may improve the accuracy of a time interval determined by the time evaluation circuit 114 and thus of an eventually determined overall reference voltage.

The circuit arrangement 110 may be configured for further determining the reference voltage from the determined time interval. Thus, an accuracy of the reference voltage or variations of the reference voltage can be monitored and not only a correct switching between a high voltage output and a low voltage output of the comparator circuit 112 for instance. As said, the reference voltage may in practice be instable over time. As an example, a voltage value of the reference voltage may drift over time, such as due to a degradation of a component or due to changing ambient conditions. Thus, in normal mode operation, a potentially false or at least imprecise or inaccurate reference voltage may be applied, which may specifically be unfavorable for safety relevant applications. Wit the presented self-test, the actual reference voltage may be determined and the reference voltage may be reset to the originally intended value again. Specifically, the reference voltage may be determined from the number of counted clock signals, such as by using the following formula:

$${V}_{Ref} = \frac{I}{C} \cdot n \cdot T ,$$

wherein V_{Ref} as said refers to the reference voltage, n refers to the number of counted clock periods, T refers to a time interval of one clock period, C refers to a capacitance of the capacitor 118 and I refers to a current provided to the capacitor 118 by the current source 120 for generating the voltage ramp. For determining the reference voltage, the circuit arrangement 110 may comprise or may at least have access to a further evaluation device, such a microcontroller, specifically a microcontroller within the same integrated circuit. However, for improving accuracy of the comparator circuit 112, it may not necessarily be required to determine an actual value of the reference voltage. The circuit arrangement 110 may instead for instance perform the self-test repeatedly and may determine a variation of the recorded time intervals, which correlates with a variation of the reference voltage. Thus, the reference voltage may also be corrected by compensating said variations. In any case, the circuit arrangement 110 may be configured for recalibrating the reference voltage. In other words, the circuit arrangement 110 may correct unintended variations of the reference voltage and specifically reset the reference voltage to the originally intended value.

The circuit arrangement 110 and/or the described self-test may specifically be used in an automotive application, such as for controlling a motor of a vehicle or a vehicle light. In the automotive field, Automotive Safety Integrity Level (ASIL) is a risk classification scheme defined by the ISO 26262-Functional Safety for Road Vehicles standard. There are four ASILs identified by the standard: ASIL A, ASIL B, ASIL C, ASIL D. ASIL D dictates the highest safety requirements and ASIL A the lowest. Hazards that are identified as QM referring to Quality Management do not dictate any safety requirements. The devices and methods presented in this disclosure may specifically be used for safety relevant applications. Thus, in the automotive field, the devices and methods presented in this disclosure may specifically be used for ASIL applications.

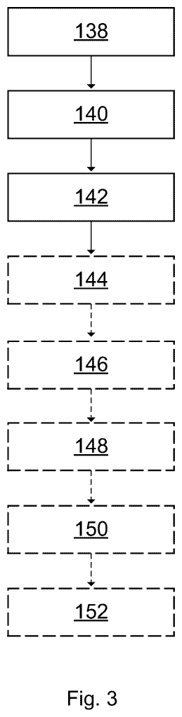

FIG. 3 illustrates a flow chart of an example of a method for performing the self-test. The method comprises the following steps. The presented method steps may be performed in the indicated order. It shall be noted, however, that a different order may also be possible. The method may comprise further method steps which are not listed. Further, one or more of the method steps may be performed once or repeatedly. Further, two or more of the method steps may be performed simultaneously or in a timely overlapping fashion. For instance, steps a) to c) may be performed in parallel and/or repeatedly. The method may at least partially be computer-implemented. Thus, one or more of the following method steps may be computer-implemented.
a) (denoted by reference numeral 138) generating a voltage ramp by using the voltage ramp generation circuit 116;
b) (denoted by reference numeral 140) continuously comparing the generated voltage ramp to a provided reference voltage by using the comparator circuit 112; and
c) (denoted by reference numeral 142) determining a time interval in which the generated voltage ramp reaches the reference voltage by using the time evaluation circuit 114.

As already indicated, step a) may comprise charging the capacitor 118, specifically by using the current source 120, and step c) may comprise counting a number of clock periods. Steps a) to c) may specifically be started with a start signal and stopped with a stop signal. The stop signal may be provided to time evaluation circuit 114 by the comparator circuit 112 when the generated voltage ramp reaches the reference voltage. The start signal may indicate a restart of the generated voltage ramp. The method may further comprise at least one of the following steps:
d) (denoted by reference numeral 144) determining the reference voltage from the determined time interval, specifically from a number of counted clock periods;
e) (denoted by reference numeral 146) repeatedly performing at least steps a) to c) and determining a variation of the determined times.
f) (denoted by reference numeral 148) recalibrating the reference voltage;
g) (denoted by reference numeral 150) comparing an input voltage to the reference voltage by using the comparator circuit 112; and
h) (denoted by reference numeral 152) multiplexing at least two of the reference voltage, the voltage ramp and the input voltage at at least one of the comparator inputs 134 and 136.

In addition to the above described examples, the following examples are disclosed herein:

Example 1: A circuit arrangement comprising:
a comparator circuit configured for comparing a voltage to a provided reference voltage;
a time evaluation circuit configured for determining a time interval between a start signal and a stop signal; and
a voltage ramp generation circuit configured for generating a voltage ramp beginning with the start signal,
wherein the circuit arrangement is configured for:
in a normal operation mode:
   comparing an input voltage to the reference voltage by using the comparator circuit; and
in a self-test mode for performing a self-test of the comparator circuit:
   generating a voltage ramp by using the voltage ramp generation circuit;
   continuously comparing the generated voltage ramp to the reference voltage by using the comparator circuit; and
   determining a time interval in which the generated voltage ramp reaches the reference voltage by using the time evaluation circuit.

Example 2: The circuit arrangement according to the preceding example, wherein the circuit arrangement is further configured for determining the reference voltage from the time interval determined in the self-test of the comparator circuit.

Example 3: The circuit arrangement according to any one of the preceding examples, wherein the circuit arrangement is further configured for repeatedly performing a self-test of the comparator circuit.

Example 4: The circuit arrangement according to the preceding example, wherein the circuit arrangement is further configured for determining a variation of the time intervals determined in the self-tests.

Example 5: The circuit arrangement according to any one of the preceding examples, wherein the self-test mode is started with the start signal and stopped with the stop signal.

Example 6: The circuit arrangement according to any one of the preceding examples, wherein the circuit arrangement is further configured for recalibrating the reference voltage.

Example 7: The circuit arrangement according to any one of the preceding examples, wherein the voltage ramp generation circuit comprises a capacitor, wherein the capacitor is configured for generating the voltage ramp and applying the voltage ramp to the comparator circuit by accumulating electric charges.

Example 8: The circuit arrangement according to the preceding example, wherein the voltage ramp generation circuit further comprises a current source, specifically a constant current source, configured for supplying the capacitor with the electric charges.

Example 9: The circuit arrangement according to the preceding example, wherein the current source is a trimmable current source.

Example 10: The circuit arrangement according to any one of the three preceding examples, wherein the voltage ramp generation circuit further comprises a discharge switch configured for discharging the capacitor with the start signal.

Example 11: The circuit arrangement according to any one of the preceding examples, wherein the comparator circuit is further configured for providing the stop signal to time evaluation circuit if the generated voltage ramp reaches the reference voltage during the self-test of the comparator circuit.

Example 12: The circuit arrangement according to any one of the preceding examples, wherein the time evaluation circuit comprises a counter configured to start counting with the start signal and to stop counting with the stop signal.

Example 13: The circuit arrangement according to the preceding example, wherein the time evaluation circuit further comprises a clock input, wherein the counter is configured for counting clock periods.

Example 14: The circuit arrangement according to any one of the preceding examples, wherein the circuit arrangement further comprises at least one multiplexer configured for multiplexing at least two of the reference voltage, the input voltage and the generated voltage ramp.

Example 15: The circuit arrangement according to the preceding example, wherein the circuit arrangement comprises a first multiplexer configured for multiplexing the reference voltage and the input voltage at a first comparator input.

Example 16: The circuit arrangement according to the preceding example, wherein the first multiplexer is configured for applying the input voltage to the first comparator input in the normal operation mode and for applying the reference voltage to the first comparator input in the self-test mode.

Example 17: The circuit arrangement according to any one of the three preceding examples, wherein the circuit arrangement comprises a second multiplexer configured for multiplexing the reference voltage and the generated voltage ramp at a second comparator input.

Example 18: The circuit arrangement according to the preceding example, wherein the second multiplexer is configured for applying the reference voltage to the second comparator input in the normal operation mode and for applying the generated voltage ramp to the second comparator input in the self-test mode.

Example 19: The circuit arrangement according to any one of the preceding examples, wherein the circuit arrangement is an integrated circuit.

Example 20: A method for performing a self-test of a comparator circuit, the method comprising:
a) generating a voltage ramp by using a voltage ramp generation circuit;
b) continuously comparing the generated voltage ramp to a provided reference voltage by using the comparator circuit; and
c) determining a time interval in which the generated voltage ramp reaches the reference voltage by using a time evaluation circuit.

Example 21: The method according to the preceding example, wherein the comparator circuit, the voltage ramp generation circuit and the time evaluation circuit are comprised by a circuit arrangement according to any one of the preceding examples referring to a circuit arrangement.

Example 22: The method according to any one of the preceding method examples, wherein step a) comprises charging a capacitor comprised by the voltage ramp generation circuit by using a current source comprised by the voltage ramp generation circuit.

Example 23: The method according to any one of the preceding method examples, wherein step c) comprises counting a number of clock periods.

Example 24: The method according to any one of the preceding method examples, further comprising:

d) determining the reference voltage from the determined time interval, specifically from a number of counted clock periods.

Example 25: The method according to the preceding example, wherein the reference voltage is determined by using the following formula:

$${V}_{Ref} = \frac{I}{C} \cdot n \cdot T ,$$

wherein V_{Ref} refers to the reference voltage, n refers to the number of counted clock periods, T refers to a time interval of one clock period, C refers to a capacitance of a capacitor comprised by the voltage ramp generation circuit, I refers to a current provided to the capacitor by using a current source comprised by the voltage ramp generation circuit.

Example 26: The method according to any one of the preceding method examples, further comprising:
e) repeatedly performing at least steps a) to c) and determining a variation of the determined times.

Example 27: The method according to any one of the preceding method examples, further comprising:
f) recalibrating the reference voltage.

Example 28: The method according to any one of the preceding method examples, wherein steps a) to c) are performed in parallel.

Example 29: The method according to any one of the preceding method examples, wherein steps a) to c) are started with a start signal and stopped with a stop signal.

Example 30: The method according to the preceding example, wherein the stop signal is provided to the time evaluation circuit by the comparator circuit if the generated voltage ramp reaches the reference voltage.

Example 31: The method according to any one of the two preceding method examples, wherein the start signal initiates a restart of the generated voltage ramp.

Example 32: The method according to any one of the preceding method examples, further comprising:
g) comparing an input voltage to the reference voltage by using the comparator circuit.

Example 33: The method according to the preceding example, wherein the input voltage is directly or indirectly provided by an external voltage supply.

Example 34: The method according to any one of the two preceding method examples, further comprising:
h) multiplexing at least two of the reference voltage, the voltage ramp and the input voltage at at least one comparator input.

Example 35: A use for an automotive application of at least one of a circuit arrangement according to any one of the preceding examples referring to a circuit arrangement and a method for performing a self-test according to any one of the preceding method examples.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A circuit arrangement comprising:
a comparator circuit configured for comparing a voltage to a provided reference voltage;
a time evaluation circuit configured for determining a time interval between a start signal and a stop signal; and
a voltage ramp generation circuit configured for generating a voltage ramp beginning with the start signal,
wherein the circuit arrangement is configured for:
in a normal operation mode:
comparing an input voltage to the reference voltage by using the comparator circuit; and
in a self-test mode for performing a self-test of the comparator circuit:
generating a voltage ramp by using the voltage ramp generation circuit;
continuously comparing the generated voltage ramp to the reference voltage by using the comparator circuit; and
determining a time interval in which the generated voltage ramp reaches the reference voltage by using the time evaluation circuit.

2. The circuit arrangement of claim 1, wherein the circuit arrangement is further configured for determining the reference voltage from the time interval determined in the self-test of the comparator circuit.

3. The circuit arrangement of claim 1, wherein the circuit arrangement is further configured for repeatedly performing a self-test of the comparator circuit and for determining a variation of the time intervals determined in the self-tests.

4. The circuit arrangement of claim 1, wherein the circuit arrangement is further configured for recalibrating the reference voltage.

5. The circuit arrangement of claim 1, wherein the voltage ramp generation circuit comprises a capacitor, wherein the capacitor is configured for generating the voltage ramp and applying the voltage ramp to the comparator circuit by accumulating electric charges.

6. The circuit arrangement of claim 5, wherein the voltage ramp generation circuit further comprises a current source, specifically a constant current source, configured for supplying the capacitor with the electric charges.

7. The circuit arrangement of claim 6, wherein the current source is a trimmable current source.

8. The circuit arrangement of claim 7, wherein the voltage ramp generation circuit further comprises a discharge switch configured for discharging the capacitor with the start signal.

9. The circuit arrangement of claim 1, wherein the comparator circuit is further configured for providing the stop signal to time evaluation circuit if the generated voltage ramp reaches the reference voltage during the self-test of the comparator circuit.

10. The circuit arrangement of claim 1, wherein the time evaluation circuit comprises a counter configured to start counting with the start signal and to stop counting with the stop signal, wherein the time evaluation circuit further comprises a clock input, wherein the counter is configured for counting clock periods.

11. The circuit arrangement of claim 1, wherein the circuit arrangement further comprises at least one multiplexer configured for multiplexing at least two of the reference voltage, the input voltage and the generated voltage ramp.

12. The circuit arrangement of claim 11, wherein the circuit arrangement comprises a first multiplexer configured for multiplexing the reference voltage and the input voltage at a first comparator input, wherein the first multiplexer is configured for applying the input voltage to the first comparator input in the normal operation mode and for applying the reference voltage to the first comparator input in the self-test mode.

13. The circuit arrangement of claim 12, wherein the circuit arrangement comprises a second multiplexer configured for multiplexing the reference voltage and the generated voltage ramp at a second comparator input, wherein the second multiplexer is configured for applying the reference voltage to the second comparator input in the normal operation mode and for applying the generated voltage ramp to the second comparator input in the self-test mode.

14. The circuit arrangement of claim 1, wherein the circuit arrangement is an integrated circuit.

15. A method for performing a self-test of a comparator circuit, the method comprising:
a) generating a voltage ramp by using a voltage ramp generation circuit;
b) continuously comparing the generated voltage ramp to a provided reference voltage by using the comparator circuit; and
c) determining a time interval in which the generated voltage ramp reaches the reference voltage by using a time evaluation circuit.

16. The method of claim 15, further comprising:
d) determining the reference voltage from the determined time interval, specifically from a number of counted clock periods.

17. The method of claim 15, wherein the reference voltage is determined by using the following formula:
$${V}_{Ref} = \frac{I}{C} \cdot n \cdot T ,$$
wherein V_{Ref} refers to the reference voltage, n refers to the number of counted clock periods, T refers to a time interval of one clock period, C refers to a capacitance of a capacitor comprised by the voltage ramp generation circuit, I refers to a current provided to the capacitor by using a current source comprised by the voltage ramp generation circuit.

18. The method of claim 15, further comprising:
e) repeatedly performing at least steps a) to c) and determining a variation of the determined times.

19. The method of claim 15, further comprising:
f) recalibrating the reference voltage.

20. The method of claim 15, further comprising: using the comparator circuit for an automotive application.
